(19) United States
(12) Patent Application Publication
(10) Pub. No.: US 2015/0076624 A1
(43) Pub. Date: Mar. 19, 2015

(54) INTEGRATED CIRCUITS HAVING SMOOTH METAL GATES AND METHODS FOR FABRICATING SAME

(71) Applicant: GLOBALFOUNDRIES, Inc., Grand Cayman (KY)

(72) Inventors: Huang Liu, Mechanicville, NY (US); Jialin Yu, Malta, NY (US); Jilin Xia, Malta, NY (US)

(73) Assignee: GLOBALFOUNDRIES, Inc., Grand Cayman (KY)

(21) Appl. No.: 14/031,839

(22) Filed: Sep. 19, 2013

(51) Int. Cl. H01L 21/28; H01L 29/49; H01L 21/3213; H01L 21/285; H01L 21/321

(52) U.S. Cl. CPC H01L 21/28079; H01L 21/28158; H01L 21/28556; H01L 21/32115; H01L 21/32136; H01L 29/495
USPC 257/412; 438/669

(57) ABSTRACT

Integrated circuits with smooth metal gates and methods for fabricating integrated circuits with smooth metal gates are provided. In an embodiment, a method for fabricating an integrated circuit includes providing a partially fabricated integrated circuit including a dielectric layer formed with a trench bound by a trench surface. The method deposits metal in the trench and forms an overburden portion of metal overlying the dielectric layer. The method includes selectively etching the metal with a chemical etchant and removing the overburden portion of metal.

### TECHNICAL FIELD

The technical field generally relates to integrated circuits and methods for fabricating integrated circuits, and more particularly relates to integrated circuits with metal gates and methods for fabricating such integrated circuits.

### BACKGROUND

As the critical dimensions of integrated circuits continue to shrink, the fabrication of gate electrodes for both planar and non-planar complementary metal-oxide-semiconductor (CMOS) transistors has advanced to replace silicon dioxide and polysilicon with high-k dielectric material and metal. A replacement metal gate process is often used to form the gate electrode. A typical replacement metal gate process begins by forming a sacrificial gate oxide material and a sacrificial gate between a pair of spacers on a semiconductor substrate. After further processing steps, such as an annealing process, the sacrificial gate oxide material and sacrificial gate are removed and the resulting trench is filled with a high-k dielectric and one or more metal layers. The metal layers can include workfunction metals as well as gate metals.

Processes such as atomic layer deposition (ALD), chemical vapor deposition (CVD), physical vapor deposition (PVD), electroplating (EP), and electroless plating (EL) may be used to deposit the one or more metal layers that form the metal gate electrode. Conventionally, such metal layers are planarized to uniform heights during the fabrication process. Under conventional processing, the metal layers are often formed with non-uniform, rough upper surfaces that increase resistance and harm device performance.

Accordingly, it is desirable to provide integrated circuits and methods for fabricating integrated circuits having improved metal gates. Also, it is desirable to provide methods for fabricating integrated circuits with metal gates that avoid the formation of non-uniform and rough upper surfaces on the metal gates. Furthermore, other desirable features and characteristics will become apparent from the subsequent detailed description and the appended claims, taken in conjunction with the accompanying drawings and the foregoing technical field and background.

### BRIEF SUMMARY

Integrated circuits with smooth metal gates and methods for fabricating integrated circuits with smooth metal gates are provided. In one exemplary embodiment, a method for fabricating an integrated circuit includes providing a partially fabricated integrated circuit including a dielectric layer formed with a trench bound by a trench surface. The method deposits metal in the trench and forms an overburden portion of metal overlying the dielectric layer. The method includes selectively etching the metal with a chemical etchant and removing the overburden portion of metal.

In accordance with another embodiment, a method for fabricating an integrated circuit includes forming trenches in a dielectric layer. The method deposits a liner overlying the dielectric layer. The method further includes filling the trenches with tungsten. A non-mechanical etching process is performed to remove tungsten outside of the trenches.

In another embodiment, an integrated circuit is provided. The integrated circuit includes a semiconductor substrate and a metal gate structure overlying the semiconductor substrate. The metal gate structure includes a gate liner and a tungsten gate electrode overlying the gate liner. The tungsten gate electrode has an upper surface with a root mean squared surface roughness of less than about 0.5 nanometers (nm).

### BRIEF DESCRIPTION OF THE DRAWINGS

Embodiments of integrated circuits having smooth metal gates and methods for fabricating such integrated circuits will hereinafter be described in conjunction with the following drawing figures, wherein like numerals denote like elements, and wherein:

FIGS. 1-13 illustrate, in cross section, a portion of an integrated circuit and method steps for fabricating an integrated circuit in accordance with various embodiments herein.

### DETAILED DESCRIPTION

The following detailed description is merely exemplary in nature and is not intended to limit the various embodiments of the integrated circuits or the methods for fabricating integrated circuits claimed herein. Furthermore, there is no intention to be bound by any expressed or implied theory presented in the preceding technical field, background or brief summary, or in the following detailed description.

Integrated circuits having smooth metal gates and methods for fabricating such integrated circuits as described herein avoid issues faced in conventional processes. For example, the integrated circuits and methods for fabricating integrated circuits described herein provide metal gates with smooth upper surfaces. Exemplary metal gates have upper surfaces with a root mean squared surface roughness of less than about 0.5 nm. As a result of the reduced surface roughness, device performance is improved. Specifically, increased surface roughness leads to increased contact resistance and hinders device performance. Increased surface roughness also leads to greater variation between contacts, leading to non-uniform and unpredictable performance. As described herein, metal gates are provided with smooth upper surfaces by reducing the amount of metal planarized during fabrication. Specifically, after the metal is deposited in the gate trench, the overburden portion of the metal is removed by a chemical, non-mechanical etch rather than by planarization. Conventional removal of the overburden of metal is performed by chemical mechanical planarization (CMP) and results in the lifting and removal of metal grains. Such grain removal causes surface roughness. The chemical, non-mechanical removal of the overburden portion described herein does not cause grain removal and results in a metal gate with a smoother surface. Further processing of the gate metal substantially retains the smooth surface achieved by the chemical, non-mechanical etch.

FIGS. 1-13 illustrate steps in accordance with various embodiments of methods for fabricating integrated circuits. Various steps in the design and composition of integrated circuits are well known and so, in the interest of brevity, many conventional steps will only be mentioned briefly herein or will be omitted entirely without providing the well-known process details. Further, it is noted that integrated circuits include a varying number of components and that single components shown in the illustrations may be representative of multiple components.

In FIG. 1, an integrated circuit 10 is partially fabricated for use in a typical replacement gate process. As shown, the partially fabricated integrated circuit 10 includes a semiconductor substrate 12. The semiconductor substrate 12 for example is a silicon material as typically used in the semiconductor industry, e.g., relatively pure silicon as well as silicon admixed with other elements such as germanium, carbon, and the like. Alternatively, the semiconductor material can be germanium, gallium arsenide, or the like. The semiconductor material may be provided as a bulk semiconductor substrate, or it could be provided on a silicon-on-insulator (SOI) substrate, which includes a support substrate, an insulator layer on the support substrate, and a layer of silicon material on the insulator layer. Alternatively, the semiconductor substrate 12 may include a compound semiconductor such as, silicon carbide, gallium arsenide, indium arsenide, or indium phosphide. Further, the semiconductor substrate 12 may optionally include an epitaxial layer. Also, the semiconductor substrate 12 may be in the form of fin structures for use in a FinFET. As shown, the semiconductor substrate is provided with a substantially planar surface 16.

As shown in FIG. 1, sacrificial gate structures 18 are formed overlying the surface 16. As used herein, “overlying” means “on” and “over”. In this regard, the sacrificial gate structures 18 may lie directly on the semiconductor substrate 12 such that they make physical contact with the semiconductor substrate 12 or they may lie over the semiconductor substrate 12 such that another material layer is interposed between the semiconductor substrate 12 and the sacrificial gate structures 18. Each exemplary sacrificial gate structure 18 includes a sacrificial gate 20 and a sacrificial cap 22 overlying the sacrificial gate 20. The sacrificial gate structures 18 can be fabricated using conventional process steps such as material deposition, photolithography, and etching. In this regard, fabrication of the sacrificial gate structures 18 may begin by forming at least one layer of sacrificial gate material overlying the surface 16. For this example, the material used for the sacrificial gates 20 is formed overlying the surface 16, and then a hard mask material used for the sacrificial caps 22 is formed overlying the sacrificial gate material. The sacrificial gate material is typically a polycrystalline silicon material, and the hard mask material is typically a silicon nitride material or a silicon oxide material. In typical embodiments, the sacrificial gate materials are blanket deposited on the semiconductor device structure in a conformal manner (using, for example, chemical vapor deposition, physical vapor deposition (PVD) or another suitable deposition technique).

The hard mask layer is photolithographically patterned to form a sacrificial gate etch mask, and the underlying the sacrificial gate material is anisotropically etched into the desired topology that is defined by the sacrificial gate etch mask. The resulting sacrificial gate structures 18 including sacrificial gates 20 and sacrificial caps 22 are depicted in FIG. 1, and have sides 24.

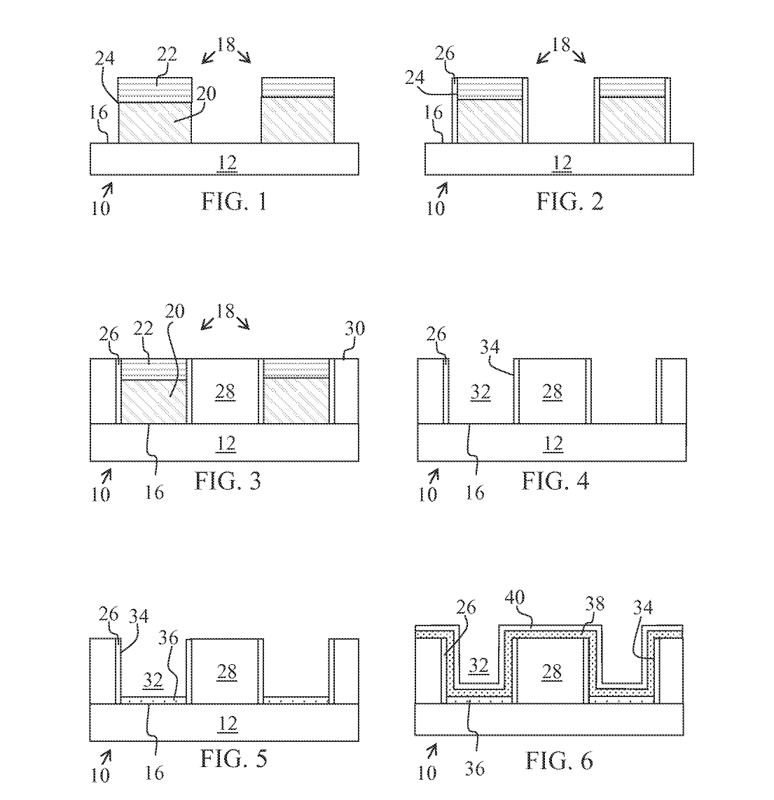

After the sacrificial gate structures 18 have been created, the process may continue by forming spacers 26 adjacent the sides 24 of the sacrificial gate structures 18. In this regard, FIG. 2 depicts the state of the partially fabricated integrated circuit 10 after the formation of the spacers 26. The spacers 26 are formed adjacent to and on the sides 24 of the sacrificial gate structures 18. In this regard, formation of the spacers 26 may begin by conformally depositing a spacer material overlying the sacrificial gate structures 18 and the surface 16. The spacer material is an appropriate insulator, such as silicon nitride, and the spacer material can be deposited in a known manner by, for example, ALD, CVD, low pressure chemical vapor deposition (LPCVD), semi-atmospheric chemical vapor deposition (SACVD), or plasma enhanced chemical vapor deposition (PECVD). The spacer material is deposited to a thickness so that, after anisotropic etching, the spacers 26 have a thickness that is appropriate for the subsequent etching steps described below. Thereafter, the spacer material is anisotropically and selectively etched to define the spacers 26. In practice, the spacer material can be etched by, for example, reactive ion etching (RIE) using a suitable etching chemistry.

After the spacers 26 have been created, other processing may be performed to form desired source/drain regions in the semiconductor substrate 18, such as etching and epitaxial deposition, stressing techniques, and ion implantations using the sacrificial gate structures as ion implantation masks. The manufacturing process may proceed by forming regions of dielectric material surrounding the spacers 26. FIG. 3 depicts the state of the partially fabricated integrated circuit 10 after dielectric material 28 has been formed. At this point in the fabrication process, previously unoccupied space around the spacers 26 has been completely filled with the dielectric material 28 (for example, by blanket deposition), and the exposed surface 30 of the partially fabricated integrated circuit 10 has been polished or otherwise planarized.

In certain embodiments, the dielectric material 28 is an interlayer dielectric (ILD) material that is initially blanket deposited overlying the surface 16, the sacrificial gate structures 18, and the spacers 26 using a well-known material deposition technique such as CVD, LPCVD, or PECVD. The dielectric material 28 is deposited such that it fills the spaces adjacent to the spacers 26 and such that it covers the spacers 26 and the sacrificial caps 22. Thereafter, the deposited dielectric material 28 is planarized using, for example, a chemical mechanical polishing tool and such that the sacrificial caps 22 serve as a polish stop indicator.

The exemplary fabrication process proceeds by removing the sacrificial gate structures 18 while leaving the spacers 26 intact or at least substantially intact. FIG. 4 depicts the state of the partially fabricated integrated circuit 10 after removal of the sacrificial gate structures 18. Removal of the sacrificial gate structures 18 results in the removal of the sacrificial caps 22 and the removal of the sacrificial gates 20. Accordingly, removal of the sacrificial gate structures 18 exposes the surface 16 between the spacers 26. Removal of the sacrificial gate structures 18 results in the formation of trenches 32 in the dielectric material 28. As shown, the trenches 32 are bounded by trench surfaces 34 formed by the spacers 26 and the surface 16.

In certain embodiments, the sacrificial gate structures 18 are removed by sequentially or concurrently etching the sacrificial caps 22 and the sacrificial gates 20 in a selective manner, stopping at the desired point. The etching chemistry and technology used for this etching step is chosen such that the spacers 26 and the dielectric material 28 are not etched (or only etched by an insignificant amount). Etching of the sacrificial gates 20 may be controlled to stop at the top of the semiconductor substrate 12. The sacrificial gate structures 18 are removed by dry etching, wet etching, or a combination of dry and wet etching.

In FIG. 5, the exemplary fabrication process continues with the formation of an interlayer material 36 on the surface 16 in the trenches 32. For example, silicon oxide may be formed as the interlayer material 36. The exemplary interlayer material 36 is selectively formed on the surface 16, and not on the trench surfaces 34 formed by spacers 26. For example, the interlayer material 36 may be formed via a chemical oxide process that oxides the exposed surface 16 of the semiconductor substrate 12. An exemplary interlayer material 36 has a thickness of from about 5 Angstroms (Å) to about 12 Å, such as about 9 Å.

As shown in FIG. 6, a high-k dielectric layer 38 is conformally deposited over the partially fabricated integrated circuit 10. Specifically, the high-k dielectric layer 38 is formed over the interlayer material 36 and along the spacers 26 in the trenches 32, and over the dielectric material 28 outside of the trenches 32. An exemplary high-k dielectric layer 38 is formed from hafnium oxide (HfO₂), hafnium silicate (HfSiOₓ) or lanthanum oxide (La₂O₃), although other high-k dielectric materials are also contemplated. In an exemplary embodiment, the high-k dielectric layer 38 is conformally deposited by ALD. The high-k dielectric layer 38 may have a thickness of about 14 Å to about 18 Å, such as about 15.6 Å.

After formation of the high-k dielectric layer 38, the exemplary method includes forming a capping layer 40. The exemplary capping layer 40 is conformally deposited over the high-k dielectric layer 38, both within and outside of the trenches 32. An exemplary capping layer 40 is titanium nitride, though other suitable materials may be used. An exemplary process for depositing the capping layer 40 is ALD. The capping layer 40 may be formed with a thickness of about 10 Å to about 20 Å. FIG. 6 illustrates the structure of the partially fabricated integrated circuit 10 after deposition of the capping layer 40.

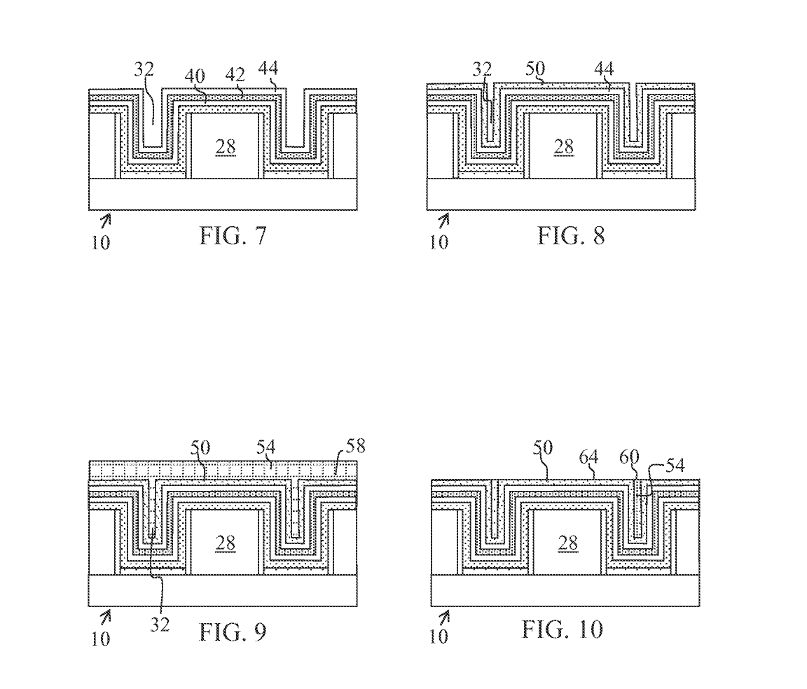

The exemplary fabrication process proceeds by forming a work function metal or stack of work function metals to provide the gate structures to be formed with desired electrical characteristics. In FIG. 7, an optional work function layer 42 is formed overlying the capping layer 40. The work function layer 42 may include a single work function metal, or a stack of work function metals. In an exemplary embodiment, the work function layer 42 is used in a P-type gate and is formed of a tantalum nitride/titanium nitride (TaN/TiN) stack, though other work function metals or metal stacks suitable for use in P-type gates may be used. The exemplary work function layer 42 is conformally deposited by ALD over the capping layer 40 within and outside of the trenches 32. The work function layer 42 may be formed with a thickness of from about 10 Å to about 20 Å.

A work function layer 44 may be formed over the work function layer 42, or over the capping layer 40 if the work function layer 42 is not present. The work function layer 44 may include a single work function metal, or a stack of work function metals. In an exemplary embodiment, the work function layer 44 is formed of titanium carbide (TiC) though other appropriate work function metals or work function metal stacks for use in N-type gates may be used. The exemplary work function layer 44 is conformally deposited by ALD over the work function layer 42 or capping layer 40 within and outside of the trenches 32. The work function layer 44 may be formed with a thickness of from about 10 Å to about 20 Å.

In FIG. 8, the exemplary fabrication process proceeds by forming liner 50 overlying the partially fabricated integrated circuit 10. Specifically, the exemplary liner 50 is conformally deposited over the work function layer 44 within and outside of the trenches 32. An exemplary liner 50 is titanium nitride (TiN), though other materials suitable for serving as a chemical etch stop may be used. In an exemplary process, the liner 50 is conformally deposited by ALD. The liner 50 may have a thickness of from about 15 Å to about 30 Å.

A gate metal 54 is deposited overlying the liner 50 of the partially fabricated integrated circuit 10 in FIG. 9. The exemplary gate metal 54 fills the trenches 32 and forms an overburden portion 58 overlying the dielectric material 28. An exemplary gate metal 54 is formed with a thickness of from about 2000 Å to about 4000 Å. Further, an exemplary gate metal 54 has an overburden portion 58 with a thickness of more than about 1000 Å. An exemplary gate metal 54 is tungsten. Further, in an exemplary process the tungsten gate metal 54 is low fluorine tungsten (LFW). An exemplary low fluorine tungsten is deposited by minimizing fluorine concentration at the interface. In another embodiment, the gate metal 54 is smooth tungsten deposited using a nitrogen assisted CVD process.

A selective etch is performed in FIG. 10 to remove the overburden portion 58 of the gate metal 54. Specifically, a chemical etch process is used with an etchant selective to the gate metal 54 relative to the liner 50. For example, for a tungsten gate metal 54 and a titanium nitride liner 50, a suitably selective dry etchant is nitrogen fluoride (NF₃). An exemplary etch has a very high tungsten etch rate as a result of using a high plasma power, and the specific selectivity is controlled by maintaining this process at a low temperature. The selective etch process does not utilize any mechanical means, such as an abrasive polishing pad as used in CMP processes, to etch the gate metal 54. Rather, the selective etch process is limited to non-mechanical forces, i.e., wet or dry chemical etchants. As a result, grains in the gate metal 54 are not mechanically lifted or pulled out during the etching process and the resulting upper surface 60 of the gate metal 54 is relatively smooth as compared to mechanically etched surfaces. For example, the upper surface 60 of the gate metal 54 has a root mean squared surface roughness of less than about 0.5 nm.

The etch process stops at the upper surface 64 of the liner 50 due to the selectivity of the chemical etchant. As a result, the upper surface 60 of the gate metal 54 is substantially aligned with the upper surface 64 of the liner 50. In an exemplary embodiment, the etch process removes from about 1000 Å to about 2000 Å of the gate metal 54.

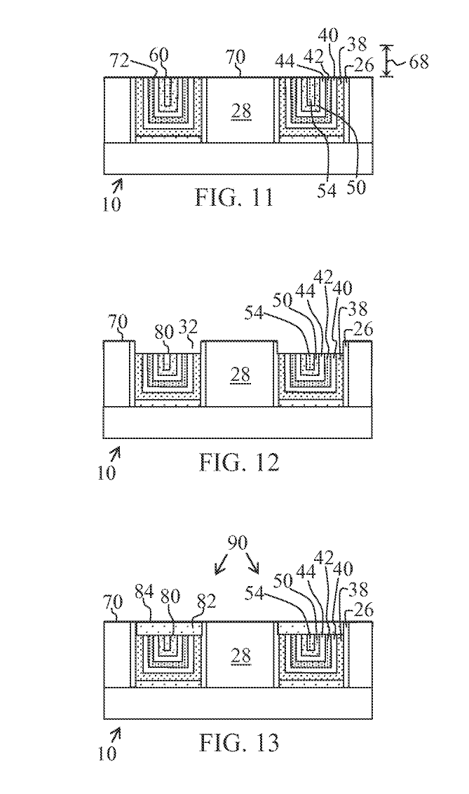

A planarization process, such as CMP, is performed in FIG. 11 to remove the portions of the high-k dielectric layer 38, capping layer 40, work function layer 42, work function layer 44, liner 50, and gate metal 54 located outside of the trenches 32 and over the dielectric material 28. The planarization process may remove a portion of the spacers 26 and the dielectric material 28. In an exemplary embodiment, the planarization process removes a portion of the gate metal 54 having a thickness, indicated by double-headed arrow 68, of less than about 25 nm, for example, less than about 20 nm, such as from about 5 nm to about 20 nm, or from about 15 nm to about 20 nm. By limiting the use of a mechanical etching means, i.e., the mechanical polishing pad used in CMP, the process herein avoids lifting, peeling or removal of grains within the gate metal 54 as the surface portion removed is substantially smaller than that removed by CMP in conventional processes. As a result of the planarization process, the upper surface 60 of the gate metal 54, the upper surface 70 of the dielectric material 28, and the upper edge 72 of the liner 50 and layers 44, 42, 40, 38 and 26 are substantially co-planar. Further, because grains are not lifted or removed by the limited CMP process, the upper surface 60 of the gate metal 54 remains smooth.

In FIG. 12, the high-k dielectric layer 38, capping layer 40, work function layer 42, work function layer 44, liner 50, and gate metal 54 are recessed within the trenches 32. As a result, the high-k dielectric layer 38, capping layer 40, work function layer 42, work function layer 44, liner 50, and gate metal 54 have a recessed surface 80 that is about 25 nm lower than the surface 70 of the dielectric material 28. An exemplary process uses a reactive ion etch (RIE) selective to the high-k dielectric layer 38, capping layer 40, work function layer 42, work function layer 44, liner 50, and gate metal 54 over the spacers 26, or uses multiple RIE processes with an etchant selective to layer(s) to be removed over the spacers 26. The etchant chemistry may include those discussed above or other suitable etchants that do not attack interfaces in the partially completed integrated circuit 10 or etch the spacers 26. The chemical etch of the gate metal 54 does not lift or remove grains in the gate metal 54, thus the recessed surface 80 of the gate metal 54 remains smooth, such as with a root mean squared surface roughness of less than about 0.5 nm.

After formation of the partially-fabricated integrated circuit 10 of FIG. 12, the high-k dielectric layer 38, capping layer 40, work function layer 42, work function layer 44, liner 50, and gate metal 54 are encapsulated with a capping material 82, as shown in FIG. 13. For example, the capping material 82 is deposited on the recessed surface 80. In an exemplary embodiment, the capping material 82 is silicon nitride. The capping material 82 may be deposited by a CVD process or other suitable process. If the capping material 82 is formed with an overburden above the upper surface 70 of the dielectric material 28, the capping material 82 may be planarized to form a surface 84 substantially coplanar with the upper surface 70 of the dielectric material 28. Alternatively, the capping material 82 may be deposited with its surface 84 substantially coplanar with the upper surface 70 of the dielectric material 28, or at a lower level than the upper surface 70 of the dielectric material 28.

As shown in FIG. 13, replacement metal gate structures 90 with gate metal 54 having smooth upper surfaces 80 are formed by the processes described herein. The smoothness of the surface of the gate metal 54 after the chemical etch of the overburden portion is retained through later processing by avoiding use of mechanical etching to remove large portions of the gate metal. After formation of the partially fabricated integrated circuit 10 of FIG. 13, further processing may be performed to complete the integrated circuit 10. For example, back-end-of-line processing may form contacts to the gate structures 90 and form interconnects between devices on the semiconductor substrate 12.

As described above, fabrication processes are implemented to form integrated circuits with smooth metal gates. Further, metal gates are formed with greater uniformity. The processes described herein avoid use of conventional mechanical planarization techniques that remove large portions of metal gate material. Conventional use of such mechanical planarization techniques causes lifting and removal of grains within the metal gate material, resulting in gate metal surface roughness. The processes described herein avoid increased gate metal surface roughness and increased contact resistance, as well as non-uniformity in gate metal surfaces that leads to unpredictable performance.

To briefly summarize, the fabrication methods described herein result in integrated circuits with improved metal gate uniformity and performance. While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method for fabricating an integrated circuit, the method comprising:
providing a partially fabricated integrated circuit including a dielectric layer formed with a trench bound by a trench surface;
depositing metal in the trench and forming an overburden portion of metal overlying the dielectric layer; and
selectively etching the metal with a chemical etchant and removing the overburden portion of metal.

2. The method of claim 1 further comprising:
selectively etching the metal within the trench to form a recessed surface; and
depositing a dielectric material over the recessed surface to form dielectric gate cap.

3. The method of claim 1 further comprising planarizing a portion of the dielectric layer and the metal, wherein the portion is less than about 25 nm thick.

4. The method of claim 3 wherein planarizing a portion of the dielectric layer and the metal comprises planarizing a portion having a thickness from about 5 nm to about 20 nm.

5. The method of claim 1 wherein depositing metal in the trench forms an overburden portion of metal overlying the dielectric layer having a thickness of more than about 1000 Å.

6. The method of claim 1 wherein depositing metal in the trench forms an overburden portion of metal overlying the dielectric layer having a thickness of from about 2000 Å to about 4000 Å.

7. The method of claim 1 wherein further comprising forming a liner overlying the trench surface, and wherein selectively etching the metal with a chemical etchant and removing the overburden portion of metal comprises selectively etching the overburden portion of metal and stopping on the liner.

8. The method of claim 1 wherein depositing metal in the trench and forming an overburden portion of metal overlying the dielectric layer comprises depositing smooth tungsten with a nitrogen assisted chemical vapor deposition process.

9. The method of claim 1 wherein depositing metal in the trench and forming an overburden portion of metal overlying the dielectric layer comprises depositing low fluorine tungsten by a low fluorine tungsten process with controlled fluorine concentration at a deposition interface.

10. A method for fabricating an integrated circuit, the method comprising:
forming trenches in a dielectric layer;
depositing a liner overlying the dielectric layer;
filling the trenches with tungsten; and
performing a non-mechanical etching process to remove tungsten outside of the trenches.

11. The method of claim 10 wherein the liner has an upper surface, and wherein performing a non-mechanical etching process to remove tungsten outside of the trenches comprises exposing the upper surface of the liner.

12. The method of claim 10 wherein the liner has an upper surface, and wherein performing a non-mechanical etching process to remove tungsten outside of the trenches comprises performing a selective etching process that stops on the upper surface of the liner.

13. The method of claim 10 wherein depositing a liner overlying the dielectric layer comprises depositing titanium nitride overlying the dielectric layer, and wherein performing a non-mechanical etching process to remove tungsten outside of the trenches comprises etching tungsten with an etchant selective to tungsten over titanium nitride.

14. The method of claim 10 wherein filling the trenches with tungsten comprises depositing smooth tungsten with a nitrogen assisted chemical vapor deposition process.

15. The method of claim 10 wherein filling the trenches with tungsten comprises depositing low fluorine tungsten by a low fluorine tungsten process with controlled fluorine concentration at a deposition interface.

16. The method of claim 10 wherein filling the trenches with tungsten comprises depositing a layer of tungsten with a thickness of about 2000 Å to about 4000 Å.

17. The method of claim 10 further comprising planarizing a portion of the liner and the tungsten after performing the non-mechanical etching process, wherein the portion is less than about 25 nm thick.

18. The method of claim 10 further comprising planarizing a portion of the liner and the tungsten after performing the non-mechanical etching process, wherein the portion is from about 5 nm to about 20 nm.

19. The method of claim 10 further comprising selectively etching the tungsten and the liner within each trench with a reactive ion etch.

20. An integrated circuit comprising:
a semiconductor substrate; and
a metal gate structure overlying the semiconductor substrate and comprising:
a gate liner; and
a tungsten gate electrode overlying the gate liner and having an upper surface with a root mean squared surface roughness of less than about 0.5 nm.
